(19) United States
(12) Patent Application Publication
(10) Pub. No.: US 2026/0305078 A1
(43) Pub. Date: Oct. 1, 2026

(54) DISPLAY PANEL AND DISPLAY APPARATUS

(71) Applicants: Hefei Visionox Technology Co., Ltd., Hefei (CN); Visionox Technology Inc., Kunshan (CN)

(72) Inventors: Zengqiang XIA, Hefei (CN); Peng QIN, Kunshan (CN)

(73) Assignees: Hefei Visionox Technology Co., Ltd., Hefei (CN); Visionox Technology Inc., Kunshan (CN)

(21) Appl. No.: 19/401,271

(22) Filed: Nov. 25, 2025

(30) Foreign Application Priority Data
Nov. 30, 2024 (CN) 202411752912.4

(51) Int. Cl. H10K 59/122; H10K 50/13

(52) U.S. Cl. CPC H10K 59/122; H10K 50/13

(57) ABSTRACT

The present application provides a display panel and a display apparatus. The display panel includes a substrate, an isolation structure, a pixel define layer, and a light-emitting functional layer. The isolation structure includes a support portion and a crown. Isolation openings are provided on the isolation structure. A pixel define layer is provided with pixel openings. A part of the light-emitting functional layer forms thinned areas. A spacing between an orthographic projection of an edge of the crown close to one of the isolation openings on the substrate and an orthographic projection of an edge of one of the pixel openings on the substrate is a first length.

### CROSS-REFERENCE TO RELATED APPLICATIONS

The present application claims priority to Chinese Patent Application No. 202411752912.4, entitled “DISPLAY PANEL AND DISPLAY APPARATUS” and filed on Nov. 30, 2024, which is incorporated herein by reference in its entirety.

### FIELD

The present application relates to the field of display technology, and in particular to a display panel and a display apparatus.

### BACKGROUND

An organic light-emitting diode (OLED) display panel is a display device that utilizes the self-luminous principle of an organic light-emitting material to achieve display. Thanks to advantages of the OLED such as rapid response, high brightness, and a full viewing angle, the organic light-emitting diode display panel becomes a highly competitive and promising display panel.

Current electronic display products, limited by their structural design, need further improvement in a display effect.

### SUMMARY

The present application is intended to resolve one of the problems in the related art at least to a specific extent.

Therefore, embodiments of the present application provide a display panel and a display apparatus, to improve the display effect of a display panel.

To achieve the embodiments of the present application is as follows: A display panel is provided, including a substrate, an isolation structure, a pixel define layer, and a light-emitting functional layer. The isolation structure is located on the substrate. The isolation structure includes a support portion and a crown. The crown is located on a side of the support portion facing away from the substrate. The isolation structure is provided with isolation openings. The isolation openings are enclosed by the support portion and the crown. The pixel define layer is located between the substrate and the isolation structure. The pixel define layer is provided with pixel openings. An orthographic projection of one of the pixel openings on the substrate is within an orthographic projection of one of the isolation openings on the substrate. The light-emitting functional layer covers one of the pixel openings and at least part of the light-emitting functional layer covers a surface on a side of the pixel define layer facing away from the substrate. The light-emitting functional layer includes thinned areas. The thinned areas are located on the side of the pixel define layer facing away from the substrate. An orthographic projection of one of the thinned areas on the substrate is arranged to at least partially surround the orthographic projection of one of the pixel openings on the substrate.

A spacing between an orthographic projection of an edge of the crown close to one of the isolation openings on the substrate and an orthographic projection of an edge of one of the pixel openings on the substrate is a first length. A spacing between the orthographic projection of the edge of the crown close to one of the isolation openings on the substrate and an orthographic projection of an edge on a side of one of the thinned areas close to one of the pixel openings on the substrate is a second length. The first length is not less than the second length.

The present application further provides a display apparatus, including the display panel in any one of the above embodiments.

In the embodiments provided in the present application, the display apparatus has the above display panel, and therefore has at least the advantages of the above display panel. For specific effects, references may be made to the above descriptions, which are not described herein again.

### BRIEF DESCRIPTION OF THE DRAWINGS

To describe the embodiments of the present application more clearly, the following briefly describes the accompanying drawings required for describing the embodiments or the prior art. Apparently, the accompanying drawings in the following description show merely some embodiments of the present application.

FIG. 1 is a schematic plan view of a display panel according to an embodiment of the present application;

FIG. 2 is a schematic view of a first sectional structure of an area A in the display panel according to an embodiment of the present application;

FIG. 3 is a schematic view of a second sectional structure of the area A in the display panel according to an embodiment of the present application;

FIG. 4 is a schematic view of a third sectional structure of the area A in the display panel according to an embodiment of the present application;

FIG. 5 is an enlarged view of a structure of an area B in FIG. 4;

FIG. 6 is a schematic view of an evaporation direction of the display panel according to an embodiment of the present application;

FIG. 7 is a schematic view of evaporation in a straight-edge scan direction in FIG. 6;

FIG. 8 is a schematic view of evaporation in a nozzle direction in FIG. 6; and

FIG. 9 is a simplified structural view of a display apparatus according to an embodiment of the present application.

### REFERENCE NUMERALS IN THE FIGURES

1: substrate; 2: isolation structure; 201: isolation opening; 202: first sidewall; 203: second sidewall; 21: support portion; 211: first end surface; 22: crown; 3: pixel define layer; 301: pixel opening; 4: light-emitting functional layer; 41: thinned area; 42: flat area; 421: first flat area; 422: second flat area; 5: encapsulation layer; 51: first cover portion; 52: connection portion; 53: second cover portion; 10: display panel; 100: display apparatus.

### DETAILED DESCRIPTION OF THE EMBODIMENTS

In order to make embodiments of the present application clearer, the present application is further described in detail below with reference to the accompanying drawings and embodiments. It should be understood that the specific embodiments described herein are merely intended to explain the present application, and are not intended to limit the present application.

It should be noted that when an element is referred to as being “fixed to” or “arranged on” another element, it may be directly or indirectly on the another element. When an element is referred to as being “connected to” another element, it may be directly or indirectly connected to the another element.

In the description of the present application, it should be understood that orientation or position relationships indicated by the terms such as “center”, “longitudinal”, “transverse”, “length”, “width”, “thickness”, “on”, “below”, “front”, “back”, “left”, “right”, “vertical”, “horizontal”, “top”, “bottom”, “inside”, “outside”, “clockwise”, “anticlockwise”, “axial direction”, “radial direction”, and “peripheral direction” are based on orientation or position relationships shown in the drawings, and are merely used to facilitate description of the present application and simplify the description, rather than indicating or implying that an apparatus or an element referred to needs to have a particular orientation or be constructed and operated in a particular orientation. Therefore, such terms cannot be understood as a limitation on the present application.

In addition, the terms “first” and “second” are merely used for description, and cannot be understood as indicating or implying relative importance or implicitly indicating a quantity of indicated embodiments. Therefore, features defined by “first” or “second” may explicitly or implicitly include one or more of the features. In the description of the present application, “a plurality of” means two or more, unless explicitly and specifically defined otherwise.

In the present application, unless otherwise explicitly specified and defined, the terms such as “mount”, “connected”, “connect”, and “fix” should be understood in a broad sense. For example, they may be a fixed connection, a detachable connection, or an integral connection, or may be a mechanical connection, an electrical connection, or mutual communication; or may be a direct connection or an indirect connection through an intermediate medium, or may be communication between interiors of two elements or interaction between two elements.

In the present application, unless otherwise explicitly specified and defined, a first feature being “on” or “under” a second feature may mean that the first feature is in direct contact with the second feature, or the first feature is in indirect contact with the second feature by using an intermediate medium. In addition, the first feature being “above”, “over”, or “on” the second feature may mean that the first feature is directly or obliquely above the second feature, or merely indicate that the first feature is at a higher horizontal position than the second feature. The first feature being “below”, “under”, and “beneath” the second feature may mean that the first feature is directly or obliquely below the second feature, or merely indicate that the first feature is at a lower horizontal position than the second feature.

In the present application, the term “one embodiment,” “some embodiments,” “example,” “specific example”, “some examples”, or the like means that specific features, structures, materials, or characteristics described in combination with the embodiment or example are included in at least one embodiment or example of the present application. In this specification, the schematic descriptions of the above terms do not necessarily refer to the same embodiment or example. In addition, the described specific features, structures, materials, or characteristics may be combined in a proper manner in any one or more embodiments or examples.

An isolation structure is provided in a display panel. The isolation structure may be configured to isolate some functional film layers in adjacent light-emitting units (also referred to as light-emitting devices), to ensure that adjacent light-emitting units do not interfere with each other, which helps improve the display effect of the display panel. However, the isolation structure may also affect light emission performance of the light-emitting units. During implementation of the present application, the inventors have found that there are the following problems in the related art. When a size of the light-emitting unit isolated by the isolation structure is excessively small, the light emission effect of the light-emitting unit is relatively poor. However, if the size of the light-emitting unit isolated by the isolation structure is excessively large, a display precision and a display effect of the display panel are affected, resulting in poor display image quality.

On this basis, an embodiment of the present application provides a display panel 10, including a substrate 1, an isolation structure 2, a pixel define layer 3, and a light-emitting functional layer 4. The isolation structure 2 is located on the substrate 1. The isolation structure 2 includes a support portion 21 and a crown 22. The crown 22 is located on a side of the support portion 21 facing away from the substrate 1. The isolation structure 2 is provided with isolation openings 201. The isolation openings 201 are enclosed by the support portion 21 and the crown 22. The pixel define layer 3 is located between the substrate 1 and the isolation structure 2. The pixel define layer 3 is provided with pixel openings 301 at a position corresponding to the isolation openings 201. An orthographic projection of one of the pixel openings 301 on the substrate 1 is within an orthographic projection of one of the isolation openings 201 on the substrate 1. One of the isolation openings 201 is in communication with one of the pixel openings 301. The light-emitting functional layer 4 covers one of the pixel openings 301 and at least part of the light-emitting functional layer covers a side of the pixel define layer 3 facing away from the substrate 1. The light-emitting functional layer 4 includes thinned areas 41. The thinned areas 41 are located on the side of the pixel define layer 3 facing away from the substrate 1. An orthographic projection of one of the thinned areas 41 on the substrate 1 is arranged to at least partially surround the orthographic projection of one of the pixel openings 301 on the substrate 1.

A spacing between an orthographic projection of an edge of the crown 22 close to one of the isolation openings 201 on the substrate 1 and an orthographic projection of an edge of one of the pixel openings 301 on the substrate 1 is a first length. A spacing between the orthographic projection of the edge of the crown 22 close to one of the isolation openings 201 on the substrate 1 and an orthographic projection of an edge on a side of one of the thinned areas 41 close to one of the pixel openings 301 on the substrate 1 is a second length. The first length is not less than the second length.

In this embodiment provided in the present application, in the display panel 10, the first length defined by the isolation structure 2 and one of the pixel openings 301 may be adjusted to be not less than the second length defined by the light-emitting functional layer 4 and the isolation structure 2, and a sufficient spacing can be defined between one of the isolation openings 201 and the pixel opening 301 for a film layer to be filled, for example, the light-emitting functional layer 4, and the film layer can be kept relatively flat. After the film layer filling the isolation opening 201 can be kept at a specific degree of flatness, the display effect of the display panel 10 can be improved to a specific extent, and the display panel can present more desirable display image quality.

The pixel define layer 3 may define, through the pixel openings 301 provided thereon, an area for exposing another light-emitting functional structures to cooperate with the light-emitting functional layer 4. Generally, the another light-emitting functional structures are located between the pixel define layer 3 and the substrate 1, and are partially exposed from the pixel openings 301. The pixel opening 301 may cooperate with the light-emitting functional layer 4, the another light-emitting functional structure, and a corresponding light-emitting functional layer, to define a size of a light emission area of a light-emitting unit and a boundary of a light emission range. In the light emission area, when a non-uniform film layer thickness exists, luminous efficiency of the light emission area is non-uniform, affecting the final display effect.

It should be noted that the light-emitting functional layer 4 may include at least one of a hole injection layer, a hole transport layer, an electron blocking layer, an organic light-emitting material layer, an electron injection layer, an electron transport layer, or a hole blocking layer.

The display panel 10 may further include an electrode layer. The electrode layer at least partially covers the light-emitting functional layer 4. The electrode layer and at least one of the hole injection layer, the hole transport layer, the electron blocking layer, the organic light-emitting material layer, the electron injection layer, the electron transport layer, or the hole blocking layer are stacked on the substrate 1. The electrode layer includes either a cathode or an anode.

In one embodiment, the hole injection layer, the hole transport layer, the electron blocking layer, the organic light-emitting material layer, the hole blocking layer, the electron transport layer, the electron injection layer, and the cathode are sequentially stacked on the substrate 1, the electrode layer is electrically connected to the isolation structure 2, and the electrode layer overlaps at least part of the isolation structure.

It should be noted that, in this embodiment of the present application, a specific shape of the isolation structure 2 is not limited, provided that an overall structure of the isolation structure 2 is wider at the top and narrower at the bottom.

Content about composition, preparation, and the like of the isolation structure 2 is further described in patents CN118251982A, 202410864269.8, PCT/CN2024/098407, PCT/CN2024/102783, PCT/CN2024/098217, PCT/CN2024/099419, PCT/CN2024/099072, CN117979755A, CN117998900A, CN117062489A, CN117580403A, CN116583155A, CN116669477A, CN117396039A, CN116669480A, CN116600606A, and CN117500332A, which are incorporated herein by reference.

Some arrangement manners of the isolation structure 2 are briefly described below through embodiments.

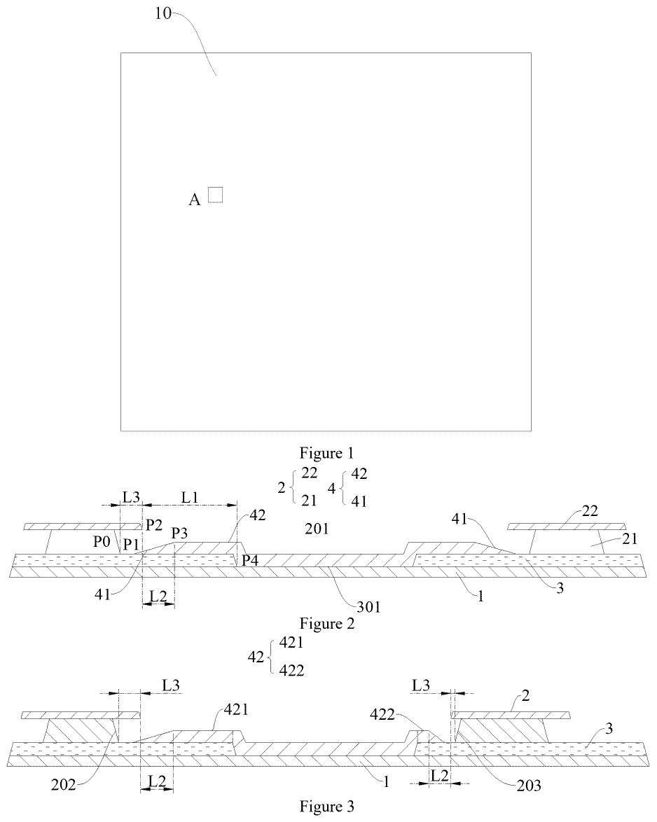

Referring to FIG. 1 and FIG. 2, the orthographic projection of one of the pixel openings 301 on the substrate 1 is within the orthographic projection of one of the isolation openings 201 on the substrate 1. The crown 22 of the isolation structure 2 has a sidewall in a peripheral direction. A plane in which the sidewall is located may be perpendicular or at an included angle to a plane in which the substrate 1 is located. The sidewall may cooperate with one of the pixel openings 301 to define the first length, or may cooperate with one of the thinned areas 41 to define the second length.

In order to facilitate description and definition of the above dimensions, in an extending direction of the substrate 1, an end of the support portion 21 close to or pointing to one of the isolation openings 201 is denoted as P0, an end of one of the thinned areas 41 close to or pointing to the isolation structure 2 is denoted as P1, an end of the crown 22 close to or pointing to one of the isolation openings 201 is denoted as P2, an end of one of the thinned areas 41 close to or pointing to one of the pixel openings 301 is denoted as P3, and an end of one of the pixel openings 301 close to or pointing to the isolation structure 2 is denoted as P4.

Referring to FIG. 2, the first length is defined as L1, and L1 is defined by P2 and P4. The second length is L2, and L2 is defined by P2 and P3. Since the first length L1 is not less than the second length L2, it can be ensured that a distance formed between an end of the isolation structure 2 facing the substrate 1 and one of the pixel openings 301 is sufficient to accommodate a light-emitting functional layer 4 having a specific size, and a part of a film layer of the light-emitting functional layer 4 located in one of the pixel openings 301 can be kept relatively flat to normally supply power, thereby helping improve the operating condition of relevant light-emitting units and helping improve the display effect of the display panel 10.

The light-emitting functional layer 4 may be arranged to cover the side of the pixel define layer 3 facing away from the substrate 1 through one of the pixel openings 301 by means of evaporation or the like. Due to an evaporation angle and an evaporation direction, during the evaporation, a part of a film layer located in an edge area may have a non-uniform thickness due to factors such as a relative position between an evaporation source and a corresponding substrate, forming one of the thinned areas 41 having a gradually inclined surface. In other words, a side surface of the thinned area 41 facing away from the pixel define layer 3 is an inclined surface, and an end of the inclined surface pointing to the isolation structure 2 is inclined toward the pixel define layer 3. Referring to FIG. 2, a film layer of the light-emitting functional layer 4 located in one of the thinned areas 41 closer to the isolation structure 2 has a smaller thickness.

When the first length L1 is less than the second length L2, only a part of the thinned areas 41 cover the pixel define layer 3, and the other part is received in one of the pixel openings 301, resulting in a relatively poor flatness of a film layer in the pixel opening 301. In this case, the light-emitting functional layer 4 with a relatively poor flatness causes a non-uniform electric field distribution, directly affecting the light-emission efficiency of the light-emitting unit. The uneven light-emitting functional layer 4 causes a varying electric field strength across different areas, leading to luminous light intensity of the light-emitting units. This ultimately manifests as non-uniform brightness of images displayed on the display panel 10. In addition, problems such as a color cast and a reduced viewing angle may occur, severely affecting image quality and viewing experience.

Therefore, through definition of a relationship between the first length L1 and the second length L2, the display effect of the display panel 10 can be effectively improved, enhancing the display quality.

In the case in which a size and a shape of the isolation structure 2 in the display panel 10 are unchanged, a larger L1 indicates a higher degree of flatness of the light-emitting functional layer 4.

In some embodiments, referring to FIG. 2, the light-emitting functional layer 4 further includes flat areas 42. Each of the flat areas 42 is located on the side of the pixel define layer 3 facing away from the substrate 1. One of the flat areas 42 is connected to one of the thinned areas 41, and one of the flat areas 42 is located on a side of one of the thinned areas 41 facing one of the pixel openings 301. In addition to the flat areas 42, the light-emitting functional layer 4 further includes a part of a film layer located in one of the pixel openings 301.

Each of the flat areas 42 is located on the side of the pixel define layer 3 facing away from the substrate 1. In the flat area 42, film layers at different positions have a relatively uniform and consistent thickness and have a relatively flat surface. One of the thinned areas 41 is connected to the part of the light-emitting functional layer 4 located in one of the pixel openings 301 through the flat area 42, which helps improve the flatness of the light-emitting functional layer 4 in the pixel opening 301, and the film layers of the light-emitting functional layer 4 located in the pixel opening 301 can be kept substantially flat, thereby facilitating more effective contact with film layers such as the electrode layer. Therefore, the film layers adjacent to the light-emitting functional layer 4 can effectively transfer charges to the light-emitting functional layer 4, helping improve use efficiency of the charges. In this way, the part of the light-emitting functional layer 4 located in the pixel opening 301 has desirable light emission uniformity and light emission brightness, thereby improving the display quality of the display panel 10.

Because the light-emitting functional layer 4 does not need to be connected to the isolation structure 2, to avoid electric leakage of a corresponding film layer (for example, a hole injection layer (HIL)), in some embodiments, the orthographic projection of one of the thinned areas 41 on the substrate 1 is arranged to partially coincide with the orthographic projection of the crown 22 close to one of the isolation openings 201 on the substrate 1, and the orthographic projection of one of the thinned areas 41 on the substrate 1 is arranged to be spaced apart from the orthographic projection of the support portion 21 close to one of the isolation openings 201 on the substrate 1.

The spacing ensures that the thinned areas 41 do not directly contact the isolation structure 2, and therefore can avoid interference of the isolation structure 2 with current transmission in the light-emitting functional layer 4, and avoid lateral leakage defects in the light-emitting functional layer 4.

Referring to FIG. 2, the support portion 21 and the crown 22 both have at least a trapezoidal sectional structure in a thickness direction, a thickness of the support portion 21 is greater than a thickness of the crown 22, and a minimum width of the crown 22 in a transverse direction is greater than a maximum width of the support portion 21 in the transverse direction. Therefore, the orthographic projection of the support portion 21 on the substrate 1 is within the orthographic projection of the crown 22 on the substrate 1. The orthographic projection of one of the thinned areas 41 on the substrate 1 can be exactly located in a part, of the orthographic projection of the crown 22 on the substrate 1, not coinciding with an orthographic projection of the support portion 21 on the substrate 1.

This structural design can effectively prevent the light-emitting functional layer 4 from contacting the isolation structure 2.

The isolation structure 2 formed through cooperation of the support portion 21 and the crown 22 has at least a T-shaped sectional structure. In some embodiments, the support portion 21 is a multi-layer structure. For example, the support portion 21 may be arranged to include at least two support sub-portions that are stacked.

In some embodiments, an orthographic projection of a support sub-portion close to the substrate on the substrate is within the orthographic projection of the crown on the substrate. An orthographic projection of a support sub-portion away from the substrate 1 on the substrate 1 is within the orthographic projection of the support sub-portion close to the substrate 1 on the substrate 1. In this case, a sectional structure of the isolation structure 2 is in a shape of an inverted trapezoid or a structure similar to the inverted trapezoid.

Specifically, a side, of the support portion 21 close to one of the isolation openings 201, facing the substrate 1 is a first end surface 211, and a spacing between an orthographic projection of an edge of the first end surface 211 on the substrate 1 and the orthographic projection of the edge of the crown 22 close to one of the isolation openings 201 on the substrate 1 is a third length L3. An end of the first end surface 211 close to or pointing to one of the isolation openings 201 is denoted as P0. In this case, the third length L3 is defined by P0 and P2 described above.

The third length L3 is used to avoid contact or overlap between the light-emitting functional layer 4 and a sidewall of the isolation structure 2.

During evaporation of the light-emitting functional layer 4 and other subsequent film layers, L3, in combination with the adjustment of an evaporation angle, enables control over an evaporation coverage of the relevant film layers, to ensure that the finally evaporated different film layers can overlap the sidewall of the isolation structure 2 or be spaced apart from the sidewall of the isolation structure 2 based on a design requirement. In other words, L3 is used to adjust a film layer distribution range during preparation using various evaporation processes.

Because the light-emitting functional layer 4 needs to be spaced apart from the corresponding sidewall of the isolation structure 2 or a peripheral area thereof to avoid overlapping, the third length L3 needs to be adjusted to achieve a proper dimension. When other conductive film layers connected to the light-emitting functional layer 4 need to overlap the corresponding sidewalls of the isolation structure 2 or the peripheral area thereof, the corresponding length L3 may be properly adjusted as needed to ensure an overlapping effect. When the other conductive film layers (for example, the electrode layer covering the light-emitting functional layer 4, which may be a cathode layer or an anode layer) connected to the light-emitting functional layer 4 do not need to overlap the corresponding sidewall of the isolation structure 2 or the peripheral area thereof based on a design requirement, the corresponding length L3 may be properly reduced to help reduce a size of the isolation structure 2. Through the adjustment of the third length L3, a design width of an inter-pixel gap is reduced, which helps increase a pixel density and improve the display effect of the display panel 10.

Specifically, the third length L3 is not greater than 0.8 μm.

Further, the third length L3 ranges from 0.3μm to 0.8 μm. The third length L3 may be adaptively adjusted within the range, for example, adjusted to 0.3 μm, 0.4 μm, 0.5 μm, 0.6 μm, 0.7 μm, or 0.8 μm.

In some embodiments, two opposite sides of the light-emitting functional layer 4 in a peripheral direction do not need not overlap the corresponding sidewall of the isolation structure 2 or the peripheral area thereof. However, to achieve a more desirable light emission effect and avoid color mixing of a light-emitting functional layer, the two opposite sides of the light-emitting functional layer 4 in the peripheral direction are usually both arranged to extend to a position above the pixel define layer 3. At the same time, the above structure facilitates normal overlapping between other conductive film layers (for example, an electrode layer, not shown in the figure) on the side of the light-emitting functional layer 4 facing away from the substrate 1 and the sidewall of the isolation structure 2.

In some embodiments, taking the electrode layer as an example, two ends of the electrode layer need to overlap the isolation structure 2. In other embodiments, one end of the electrode layer needs to overlap the isolation structure 2. In this case, a distribution range of the light-emitting functional layer 4 in one of the isolation openings may be adjusted as needed.

Referring to FIG. 3, each of the flat areas 42 is an annular structure, and is arranged in the corresponding isolation opening 201 in one-to-one correspondence. In a sectional direction perpendicular to the substrate 1, one of the flat areas 42 in one of the isolation openings 201 includes a first flat area 421 and a second flat area 422 arranged oppositely. The first flat area 421 and the second flat area 422 are respectively located on two sides of one of the pixel openings 301, and a length of the first flat area 421 is greater than a length of the second flat area 422. On the isolation structure 2, a sidewall arranged corresponding to the first flat area 421 is a first sidewall 202, a sidewall arranged corresponding to the second flat area 421 is a second sidewall 203, and the third length L3 corresponding to the first sidewall 202 is greater than the third length L3 corresponding to the second sidewall 203.

An electrode layer located above the second flat area 422 of the light-emitting functional layer 4 does not need to overlap the sidewall of the isolation structure 2. Therefore, the third length L3 corresponding to the film layer may be reduced to a specific extent while it is ensured that the light-emitting functional layer 4 does not overlap the sidewall of the isolation structure 2, which can help, to a specific extent, reduce a size of a corresponding area of the isolation structure 2, thereby minimizing a distance between two adjacent isolation openings 201. This increases arrangement density of the light-emitting units without affecting independent light emission of two adjacent light-emitting units or causing failures such as current crosstalk or electric leakage, which achieves increased arrangement density of the light-emitting units, thereby improving the display image quality of the display panel 10 and improving the display effect.

Specifically, shapes and extension statuses of the light-emitting functional layers 4 located in different isolation openings 201 may be adjusted according to an actual requirement, which are not limited in this embodiment and other similar embodiments.

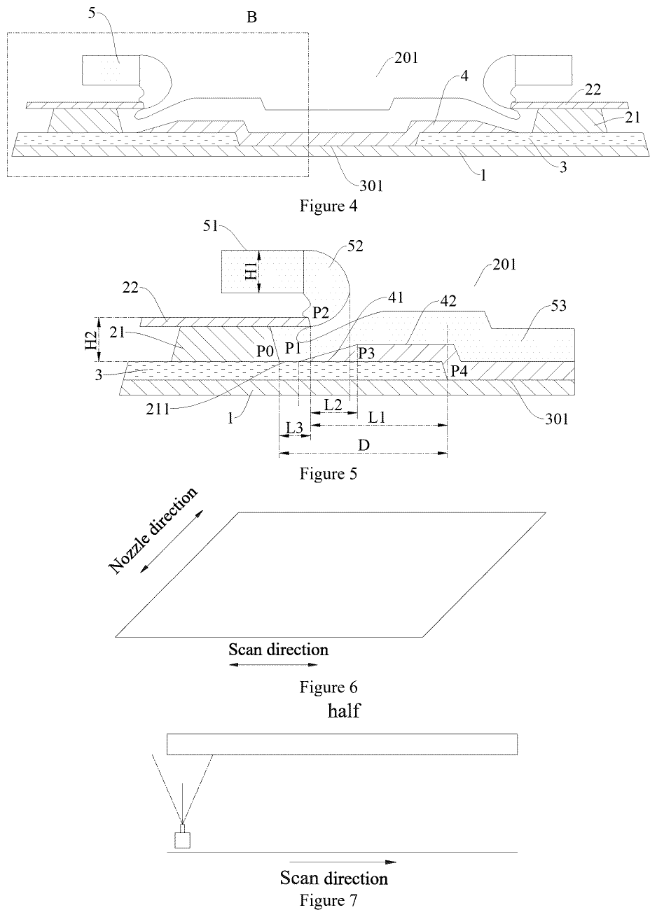

Referring to FIG. 4 and FIG. 5, the display panel 10 further includes an encapsulation layer 5. The encapsulation layer 5 is configured to encapsulate the light-emitting unit located in the corresponding isolation opening 201.

The encapsulation layer 5 may be a thin film structure prepared by using a chemical vapor deposition (CVD) technology.

Specifically, the encapsulation layer 5 includes first cover portions 51 and connection portions 52. The first cover portions 51 are located on a side of the isolation structure 2 facing away from the substrate 1 and are in contact with the edge of the crown 22 close to the isolation openings 201 through the connection portions 52. At least part of the connection portions 52 protrude toward the isolation openings 201 relative to the crown 22.

One of the connection portions 52 is in contact with and connected to the crown 22 through a sidewall on an end of the crown 22 pointing to one of the isolation openings 201. In this case, at least part of a structure of the connection portion 52 can protrude toward the isolation opening 201 relative to the crown 22 and block a part of the light-emitting functional layer 4 located below the crown. Correspondingly, one of the first cover portions 51 is located on a side of the crown 22 facing away from the substrate 1 through the connection portion 52, i.e., located above the crown 22, and a specific spacing is retained between the first cover portion 51 and a surface on the side of the crown 22 facing away from the substrate 1.

Because the connection portion 52 may block light emitted by the light-emitting unit located below the connection portion, to minimize the impact of the connection portion 52 on the light, in some embodiments, an orthographic projection one of the connection portions 52 on the substrate 1 at least partially overlaps the orthographic projection of one of the thinned areas 41 on the substrate 1, and the orthographic projection of the edge on the side of the thinned areas 41 close to one of the pixel openings 301 on the substrate 1 is outside the orthographic projection of one of the connection portions 52 on the substrate 1.

In some embodiments, the orthographic projection of one of the connection portions 52 on the substrate 1 is within the orthographic projection of one of the thinned areas 41 on the substrate 1.

Referring to FIG. 5, a specific spacing exists between an orthographic projection of an end of one of the connection portions 52 facing one of the pixel openings 301 on the substrate 1 and an orthographic projection of an end of one of the thinned areas 41 facing one of the pixel openings 301 on the substrate 1, which can ensure that the connection portion 52 can and can only block a part of the thinned areas 41 of the light-emitting functional layer 4. Because the thinned areas 41 of the light-emitting functional layer 4 are entirely located on the side of the pixel define layer 3 facing away from the substrate 1, the structure can ensure that the connection portion 52 does not block the film layer located in the pixel opening 301, thereby ensuring as much as possible that the corresponding light-emitting unit can achieve a desirable light emission effect.

In other words, a length of the part of the connection portion 52 protruding relative to the crown 22 is less than the second length L2. In addition, when a surface on the side of the pixel define layer 3 facing away from the substrate 1 is further covered by the flat areas 42 of the light-emitting functional layer 4, a spacing exists between an orthographic projection of one of the flat areas 42 on the substrate 1 and the orthographic projection of one of the connection portions 52 on the substrate 1. In other words, in this case, the connection portion 52 does not block the flat area 42 of the light-emitting functional layer 4, which can reduce shielding of the encapsulation layer 5 on the display panel 10 to a specific extent, and can optimize a viewing angle of the display panel 10.

Specifically, a size of one of the flat areas 42 is defined by P3 and P4 described above. When the light-emitting functional layer 4 includes the flat areas 42, one of the flat areas 42 is located between P3 and P4.

Referring to FIG. 5, a size of an end of one of the connection portions 52 for connecting to the crown 22 is greater than or equal to a size of the side of the crown 22, and a size of an end for connecting to one of the first cover portions 51 is substantially the same as a size of the first cover portion 51. In this case, an overall shape of the connection portion 52 is subjected to impact from a shape of the first cover portion 51. A larger thickness of one of the first cover portions 51 indicates a larger length of an end of one of the connection portions 52 protruding toward one of the pixel openings 301.

To alleviate the problem at least to a specific extent, in some embodiments, the thickness of the first cover portion 51 is set to a first thickness H1. The second length L2 is not less than half of the first thickness H1.

Specifically, the first cover portion 51 is a film layer structure having a uniform and consistent thickness and a flat surface.

In consideration of pixel density, the second length L2 cannot be excessively large. Therefore, in some embodiments, the second length L2 is further set to be not greater than the first thickness H1.

To further ensure that the first thickness H1 does not cause the connection portions 52 to block the flat areas 42 of the light-emitting functional layer 4, the second length L2 needs to be set to vary with the first thickness H1. The two are positively correlated. It should be noted that a maximum value of the second length L2 cannot exceed the first length L1.

In other words, a larger thickness of one of the first cover portions 51 indicates a larger second length L2 formed between the isolation structure 2 and one of the pixel openings 301, to more effectively adapt to thickness adjustment of the encapsulation layer 5, thereby ensuring that both the first length L1 and the second length L2 can vary with the encapsulation layer 5.

In addition, the thickness of the first cover portion 51 exerts impact on an optical effect of relevant light-emitting units. During emission of light, some of the light is emitted through the first cover portion 51 and refracted.

In some embodiments, the second length L2 is not less than half of the first thickness H1.

Since the relationship between the first length L1 and the second length L2 is defined above, it may be considered that the first length L1 is defined as follows: L1≥max[X*H1, L2], where X is a thickness coefficient.

In some embodiments of the present application, L1 may be comprehensively determined based on a design requirement, which may be selected to be greater than or equal to a value related to the thickness of the encapsulation layer 5, or may be set to a value greater than or equal to the second length L2, provided that the selected value is the maximum value among the two parameters, to ensure that the film layer of the display panel 10 located in one of the pixel openings 301 is kept relatively flat while minimizing blocking of the pixel opening 301 and the film layer of the flat area 42 located above the pixel define layer 3 by the encapsulation layer 5.

Specifically, the thickness coefficient X may range from 0.5 to 1.0. A specific value of the thickness coefficient may be adjusted based on a design requirement. The value of the thickness coefficient X may be set to any value ranging from 0.5 to 1.0, for example, 0.5, 0.6, 0.7, 0.8, 0.9, or 1.0.

Specifically, the first thickness H1 ranges from 0.6 μm to 2.0 μm. A specific value range of the first thickness may be adjusted according to an actual requirement. For example, a value of the first thickness H1 may be any one of 0.6 μm, 0.7 μm, 0.8 μm, 0.9 μm, 1.0 μm, 1.1 μm, 1.2 μm, 1.3 μm, 1.4 μm, 1.5 μm, 1.6 μm, 1.7 μm, 1.8 μm, 1.9 μm, or 2.0 μm.

Specifically, the first thickness H1 may be further defined to be ranging from 1.0 μm to 2.0 μm. In this case, H1 may be any one of 1.0 μm, 1.1 μm, 1.2 μm, 1.3 μm, 1.4 μm, 1.5 μm, 1.6 μm, 1.7 μm, 1.8 μm, 1.9 μm, or 2.0 μm.

In other embodiments, the encapsulation layer 5 further includes second cover portions 53. The second cover portions 53 cover the light-emitting functional layer 4 and a side surface of the isolation structure 2 close to the isolation openings 201.

Specifically, a part of the second cover portions 53 cover at least part of a peripheral side of the support portion 21 close to the isolation openings 201, and may further cover at least part of a surface on a side of the crown 22 close to the substrate 1.

One of the connection portions 52 may be connected to one of the first cover portions 51 and one of the second cover portions 53 and form a continuous film layer structure of the encapsulation layer 5, to ensure that the encapsulation layer 5 achieves a desirable encapsulation effect for one of the isolation openings 201. Generally, a thickness of the first cover portion 51 and a thickness of the second cover portion 53 are positively correlated.

Because the first length L1 is further related to the second length L2, obtaining of the second length L2 needs to be defined.

In some embodiments, the range of the second length L2 is related to the thickness of the isolation structure 2. A thickness of the isolation structure 2 is defined as the second thickness H2. A larger value of H2 indicates a larger second length L2. The two are positively correlated.

In some embodiments, the relationship between the second length L2 and the second thickness H2 may be:
L2=H2*S, where S is a ratio.

In this embodiment, S ranges from 0.577 to 2.246.

During evaporation, an included angle between an evaporation source (such as an evaporated metal atom source) and a surface normal of the substrate being coated is referred to as an evaporation angle. The evaporation angle indicates an incident angle at which a particle flux of an evaporated substance reaches a substrate.

The value of the second length L2 is further related to the evaporation angle. When the thickness of the isolation structure 2 remains fixed, adjustment of the evaporation angle of the light-emitting functional layer 4 affects the second length L2. A larger evaporation angle θ of the light-emitting functional layer 4 indicates larger L2 defined by the light-emitting functional layer 4 prepared through evaporation and the isolation structure 2.

It means that a positive correlation exists between the ratio S of the second length L2 to the second thickness H2 and the evaporation angle θ of the light-emitting functional layer 4.

A trigonometric function is used below to define the relationship between the evaporation angle θ of the light-emitting functional layer 4 and the ratio S.

Specifically, the relationship between the ratio S and the evaporation angle θ of the light-emitting functional layer 4 is: S=tan(θ).

In other words, a larger tangent value of the evaporation angle θ corresponding to the light-emitting functional layer 4 indicates a larger ratio S of the second length L2 to the second thickness H2.

It should be noted that due to machining errors, the ratio S and tan(θ) may not completely the same. To ensure reliability of the product, in some embodiments, the relationship between S and tan(θ) may be set to:

S=tan(θ)+i, where i represents an allowable error value of the design, and i may be positive or negative.

In some embodiments, the ratio S of the second length L2 to the second thickness H2 does not exceed the tangent value of the evaporation angle of the light-emitting functional layer 4.

Specifically, the ratio S of the second length L2 to the second thickness H2 is equal to the tangent value of the evaporation angle of the light-emitting functional layer 4.

The second length L2 is defined as follows:
L2=H2*tan(θ).

In some embodiments, the second thickness H2 may range from 0.45 μm to 1.5 μm. The specific value range of the second thickness may be adjusted according to an actual requirement. For example, the value of the second thickness H2 may be any one of 0.45 μm, 0.50 μm, 0.55 μm, 0.60 μm, 0.65 μm, 0.70 μm, 0.75 μm, 0.80 μm, 0.85 μm, 0.90 μm, 0.95 μm, 1.10 μm, 1.15 μm, 1.20 μm, 1.25 μm, 1.30 μm, 1.35 μm, 1.40 μm, 1.45 μm, or 1.50 μm.

Specifically, the second thickness H2 may be further defined to be ranging from 0.7 μm to 0.9 μm. In this case, the second thickness H2 may be any one of 0.7 μm, 0.75 μm, 0.8 μm, 0.85 μm, or 0.9 μm. Specifically, the second thickness H2 may be 0.8 μm. The evaporation angle of the light-emitting functional layer 4 may vary within a specific range depending on a processing requirement and the adjustment of the second thickness H2.

In addition, during preparation of a light-emitting functional layer 4 through evaporation, two evaporation angles θ facing the same isolation opening 201 may be asymmetric, resulting in different shapes of two opposite sides of the prepared light-emitting functional layer 4. In particular, different lengths L2 may be formed. Referring to FIG. 3, the evaporation source in FIG. 3 is not arranged to directly face the isolation openings 201, resulting in different evaporation angles on left and right sides in FIG. 3. Correspondingly, two sides of the prepared light-emitting functional layer 4 are asymmetrical, the two lengths L2 are different, and a value of L2 on the side with the larger evaporation angle is significantly larger. Certainly, when the evaporation source is arranged to directly face the isolation openings 201, evaporation angles on the left and right sides in FIG. 2 are substantially the same. Correspondingly, the prepared light-emitting functional layer 4 is substantially symmetric, and values of the two lengths L2 are substantially the same.

Specifically, the evaporation angle θ may range from 30° to 70°, for example, may be 30°, 35°, 40°, 45°, 50°, 55°, 60°, 65°, or 70°. Generally, the evaporation angle of the light-emitting functional layer 4 may be 60°, or may be 66°.

The side, of the support portion 21 close to one of the isolation openings 201, facing the substrate 1 is the first end surface 211, and a spacing between the orthographic projection of the edge of the first end surface 211 on the substrate 1 and the orthographic projection of the edge of one of the pixel openings 301 on the substrate 1 is a fourth length D.

The fourth length D is a distance between the side of the isolation structure 2 facing the substrate 1 and the pixel opening 301 formed on the pixel define layer 3. The fourth length D is defined by P0 and P4 described above.

Specifically, D=L1+L3.

The isolation opening 201 is used for arranging the light-emitting unit.

Referring to FIG. 5, at least part of the light-emitting unit is located in one of the isolation openings 201 and the pixel opening 301 in the figure. The light-emitting unit includes a light-emitting functional layer 4, a cathode layer, and an anode layer. Not all corresponding film layer structures are depicted in FIG. 5.

In some embodiments, the light-emitting functional layer 4 has a first light-emitting functional layer, a second light-emitting functional layer, and a third light-emitting functional layer that emit light of different colors. A wavelength of emergent light of the first light-emitting functional layer is less than a wavelength of emergent light of the second light-emitting functional layer, and the wavelength of the emergent light of the second light-emitting functional layer is less than a wavelength of emergent light of the third light-emitting functional layer. Any one of the first light-emitting functional layer, the second light-emitting functional layer, and the third light-emitting functional layer is arranged in one of the isolation openings 201.

Based on a design requirement, an isolation opening 201 is merely used for placing a light-emitting functional layer 4 having a corresponding emergent light wavelength.

Because different light-emitting units need to be respectively arranged in different isolation openings 201 of the display panel 10, and wavelengths emitted by the different light-emitting units are different, values of D corresponding to the light-emitting units that emit light of different colors need to be adjusted as needed, to optimize the display effect of the display panel 10 and equalize light emission brightness and color performance of the light-emitting units that emit light of different colors. Through the adjustment of the values of D, emergence angles of the light-emitting units that emit light of different colors to film layers such as the encapsulation layer 5 during light emergence can be changed, and optimization and adjustment of a final light emission effect during subsequent light refraction are achieved.

Certainly, film layer thicknesses of the light-emitting units of different colors are not the same. As the film layer thicknesses of the light-emitting units change, the values of D sequentially increase.

In some embodiments, to further optimize the display effect of the display panel 10 and reduce the design width of the pixel gap, values of L1 (or values of D) in the isolation openings 201 for arranging different light-emitting units are set to be different.

Specifically, the fourth length D in one of the isolation openings 201 having the first light-emitting functional layer is less than the fourth length D in one of the isolation openings 201 having the second light-emitting functional layer. In other words, the first length L1 in one of the isolation openings 201 having the first light-emitting functional layer is less than the first length L1 in one of the isolation openings 201 having the second light-emitting functional layer.

Specifically, the fourth length D in one of the isolation openings 201 having the second light-emitting functional layer is less than the fourth length D in one of the isolation openings 201 having the third light-emitting functional layer. In other words, the first length L1 in one of the isolation openings 201 having the second light-emitting functional layer is less than the first length L1 in one of the isolation openings 201 having the third light-emitting functional layer.

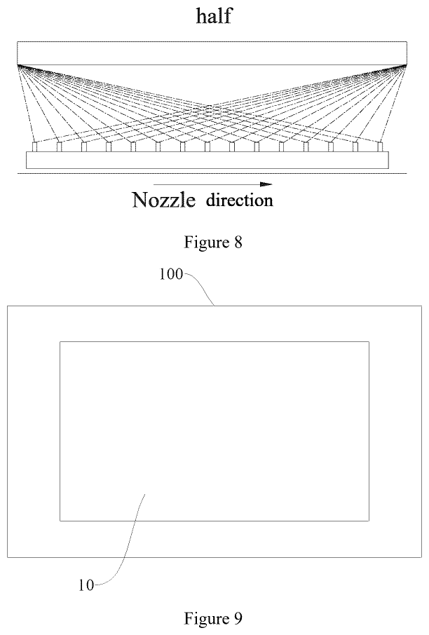

In some embodiments, emergent light of the first light-emitting functional layer is set to blue, which is denoted as B, emergent light of the second light-emitting functional layer is set to green, which is denoted as G, and emergent light of the third light-emitting functional layer is set to red, which is denoted as R. Correspondingly, the corresponding values of D in the isolation openings 201 respectively used for placing B, G, and R sequentially increase. Correspondingly, in accordance with a relationship between a shape of each light-emitting unit and the first length L1, during the evaporation, referring to FIG. 6 to FIG. 8, the first length L1 along a straight-edge scan direction may be properly reduced, and the first length L1 in a nozzle direction is greater than the first length L1 in the straight-edge scan direction. It should be noted that in a direction parallel to the plane in which the substrate 1 is located, the straight-edge scan direction and the nozzle direction are arranged to intersect. In one embodiment, the straight-edge scan direction is arranged perpendicular to the nozzle direction.

In other embodiments, a dimension of the light-emitting functional layer 4 located in the corresponding isolation opening 201 in a horizontal direction is positively correlated with the cathode layer.

It may be understood that, in the display panel 10 provided in this embodiment of the present application, the first length L1 between the isolation structure 2 and one of the pixel openings 301 may be adjusted to be not less than the second length L2 defined by the light-emitting functional layer 4 and the isolation structure 2, and a sufficient spacing can be defined between one of the isolation openings 201 and the pixel opening 301 for a film layer to be filled, for example, the light-emitting functional layer 4, and the film layer can be kept relatively flat. After the film layer filling the isolation opening 201 can be kept at a specific degree of flatness, the display effect of the display panel 10 can be improved to a specific extent, and the display panel can present more desirable display image quality. In addition, in the display panel 10, the distance between the isolation structure 2 and one of the pixel openings 301 may be adjusted based on the dimension of the side of one of the connection portions 52 in the encapsulation layer 5 protruding toward one of the pixel openings 301, and the orthographic projection of one of the connection portions 52 on the substrate 1 is outside one of the pixel openings 301, thereby reducing blocking of the light-emitting functional layer 4 located in the corresponding pixel opening 301 by the connection portion 52 of the encapsulation layer 5, and reducing impact of a viewing angle on the display effect. The thickness of the first cover portion 51 in the encapsulation layer 5 is positively correlated with the distance between the isolation structure 2 and one of the pixel openings 301. A larger thickness of the cover portion indicates a larger distance between the isolation structure 2 and one of the pixel openings 301. In the display panel 10, the third length below the isolation structure 2 may be further adjusted through adjustment of the thickness of the isolation structure 2, to satisfy an overlapping requirement when the isolation structure 2 needs to overlap a conductive film layer (for example, an electrode layer). When the isolation structure 2 does not need to overlap the conductive film layer, the design width of the pixel gap may be reduced through adjustment of the third length, which helps increase the pixel density and improve the display effect of the display panel 10.

Referring to FIG. 9, in another embodiment of the present application, a display apparatus 100 is further provided. The display apparatus 100 includes the display panel 10 described in any one of the above embodiments.

In this embodiment provided in the present application, the display apparatus 100 has the above display panel 10, and therefore has at least the advantages of the above display panel 10. For specific effects, references may be made to the specific description in the above embodiments, which are not described herein again.

The display apparatus 100 provided in this embodiment may be a product or a component with a display function, such as a mobile phone, a notebook computer, a tablet computer, a smart watch, a smart band, a navigator, a display, or a personal digital assistant (PDA).

The above descriptions are merely some embodiments of the present application, and are not intended to limit the present application. Any modification, equivalent replacement, or improvement made without departing from the spirit and principle of the present application shall fall within the protection scope of the present application.

What is claimed is:

1. A display panel, comprising:
a substrate;
an isolation structure located on the substrate, wherein the isolation structure comprises a support portion and a crown, the crown is located on a side of the support portion facing away from the substrate, the isolation structure is provided with a plurality of isolation openings, and the isolation openings are enclosed by the support portion and the crown;
a pixel define layer located between the substrate and the isolation structure, wherein the pixel define layer is provided with a plurality of pixel openings, and an orthographic projection of one of the pixel openings on the substrate is within an orthographic projection of one of the isolation openings on the substrate; and
a light-emitting functional layer, wherein the light-emitting functional layer covers one of the pixel openings and at least part of the light-emitting functional layer covers a surface on a side of the pixel define layer facing away from the substrate, the light-emitting functional layer comprises a plurality of thinned areas, the thinned areas are located on the side of the pixel define layer facing away from the substrate, and an orthographic projection of one of the thinned areas on the substrate is arranged to at least partially surround the orthographic projection of one of the pixel openings on the substrate,
wherein a spacing between an orthographic projection of an edge of the crown close to one of the isolation openings on the substrate and an orthographic projection of an edge of one of the pixel openings on the substrate is a first length, a spacing between the orthographic projection of the edge of the crown close to one of the isolation openings on the substrate and an orthographic projection of an edge on a side of one of the thinned areas close to one of the pixel openings on the substrate is a second length, and the first length is not less than the second length.

2. The display panel according to claim 1, further comprising an encapsulation layer, wherein the encapsulation layer comprises a plurality of first cover portions and a plurality of connection portions, the first cover portions are located on a side of the isolation structure facing away from the substrate and are in contact with the edge of the crown close to the isolation openings through the connection portions, and at least part of the connection portions protrude toward the isolation openings relative to the crown;
the encapsulation layer further comprises a plurality of second cover portions, and the second cover portions cover at least the light-emitting functional layer;
the second cover portions further cover at least part of a peripheral side of the support portion close to the isolation openings; and
the second cover portions further cover at least part of a surface on a side of the crown close to the substrate.

3. The display panel according to claim 2, wherein an orthographic projection of one of the connection portions on the substrate at least partially overlaps the orthographic projection of one of the thinned areas on the substrate, and the orthographic projection of the edge on the side of the thinned areas close to one of the pixel openings on the substrate is outside the orthographic projection of one of the connection portions on the substrate; or the orthographic projection of one of the connection portions on the substrate is within the orthographic projection of one of the thinned areas on the substrate.

4. The display panel according to claim 2, wherein a thickness of one of the first cover portions is a first thickness, and the second length is not less than half of the first thickness.

5. The display panel according to claim 4, wherein the second length is not greater than the first thickness; and
a relationship between the first length and the second length satisfies L1≥max[X*H1, L2], wherein L1 is the first length, L2 is the second length, H1 is the first thickness, X is a thickness coefficient, and the thickness coefficient X ranges from 0.5 to 1.0.

6. The display panel according to claim 4, wherein the first thickness ranges from 0.6 μm to 2.0 μm.

7. The display panel according to claim 1, wherein a thickness of the isolation structure is a second thickness, and the second length is positively correlated with the second thickness; and
a ratio of the second length to the second thickness ranges from 0.577 to 2.246.

8. The display panel according to claim 7, wherein the ratio of the second length to the second thickness does not exceed a tangent value of an evaporation angle of the light-emitting functional layer; or
the ratio of the second length to the second thickness is a tangent value of an evaporation angle of the light-emitting functional layer.

9. The display panel according to claim 7, wherein the second thickness ranges from 0.45 μm to 1.5 μm.

10. The display panel according to claim 1, wherein the orthographic projection of one of the thinned areas on the substrate partially coincides with an orthographic projection of the crown close to one of the isolation openings on the substrate; and
the orthographic projection of each of the thinned areas on the substrate is spaced apart from an orthographic projection of the support portion close to one of the isolation openings on the substrate.

11. The display panel according to claim 1, wherein the light-emitting functional layer further comprises a plurality of flat areas, each of the flat areas is located on the side of the pixel define layer facing away from the substrate, one of the flat areas is connected to one of the thinned areas, and one of the flat areas is located on a side of one of the thinned areas facing one of the pixel openings.

12. The display panel according to claim 11, wherein an orthographic projection of the support portion on the substrate is within an orthographic projection of the crown on the substrate;
the support portion comprises at least two support sub-portions that are stacked, and an orthographic projection of the support sub-portion away from the substrate on the substrate is within an orthographic projection of the support sub-portion close to the substrate on the substrate; and
the orthographic projection of the support sub-portion close to the substrate on the substrate is within an orthographic projection of the crown on the substrate.

13. The display panel according to claim 12, wherein a side, of the support portion close to one of the isolation openings, facing the substrate is a first end surface, a spacing between an orthographic projection of an edge of the first end surface on the substrate and the orthographic projection of the edge of the crown close to one of the isolation openings on the substrate is a third length, and the third length ranges from 0.3 μm to 0.8 μm.

14. The display panel according to claim 13, wherein in a sectional direction perpendicular to the substrate, one of the flat areas in one of the isolation openings comprises a first flat area and a second flat area arranged oppositely, the first flat area and the second flat area are respectively located on two sides of one of the pixel openings, and a length of the first flat area is greater than a length of the second flat area; and
a sidewall of the isolation structure that is arranged corresponding to the first flat area is a first sidewall, a sidewall of the isolation structure that is arranged corresponding to the second flat area is a second sidewall, and the third length corresponding to the first sidewall is greater than the third length corresponding to the second sidewall.

15. The display panel according to claim 13, wherein the light-emitting functional layer has a first light-emitting functional layer, a second light-emitting functional layer, and a third light-emitting functional layer that emit light of different colors, a wavelength of emergent light of the first light-emitting functional layer is less than a wavelength of emergent light of the second light-emitting functional layer, and the wavelength of the emergent light of the second light-emitting functional layer is less than a wavelength of emergent light of the third light-emitting functional layer; and
any one of the first light-emitting functional layer, the second light-emitting functional layer, or the third light-emitting functional layer is arranged in one of the isolation openings.

16. The display panel according to claim 15, wherein a spacing between the orthographic projection of the edge of the first end surface on the substrate and the orthographic projection of the edge of one of the pixel openings on the substrate is a fourth length, and the fourth length is a sum of the first length and the third length;
the fourth length in one of the isolation openings having the first light-emitting functional layer is less than the fourth length in one of the isolation openings having the second light-emitting functional layer; and
the fourth length in one of the isolation openings having the second light-emitting functional layer is less than the fourth length in one of the isolation openings having the third light-emitting functional layer.

17. A display apparatus, comprising:
a display panel, comprising:
a substrate;
an isolation structure located on the substrate, wherein the isolation structure comprises a support portion and a crown, the crown is located on a side of the support portion facing away from the substrate, the isolation structure is provided with a plurality of isolation openings, and the isolation openings are enclosed by the support portion and the crown;
a pixel define layer located between the substrate and the isolation structure, wherein the pixel define layer is provided with a plurality of pixel openings, and an orthographic projection of one of the pixel openings on the substrate is within an orthographic projection of one of the isolation openings on the substrate; and
a light-emitting functional layer, wherein the light-emitting functional layer covers one of the pixel openings and at least part of the light-emitting functional layer covers a surface on a side of the pixel define layer facing away from the substrate, the light-emitting functional layer comprises a plurality of thinned areas, the thinned areas are located on the side of the pixel define layer facing away from the substrate, and an orthographic projection of one of the thinned areas on the substrate is arranged to at least partially surround the orthographic projection of one of the pixel openings on the substrate,
wherein a spacing between an orthographic projection of an edge of the crown close to one of the isolation openings on the substrate and an orthographic projection of an edge of one of the pixel openings on the substrate is a first length, a spacing between the orthographic projection of the edge of the crown close to one of the isolation openings on the substrate and an orthographic projection of an edge on a side of one of the thinned areas close to one of the pixel openings on the substrate is a second length, and the first length is not less than the second length.
